(19) United States
(12) Patent Application Publication
(10) Pub. No.: US 2025/0301836 A1
(43) Pub. Date: Sep. 25, 2025

(54) METHOD OF MANUFACTURING MICRO LED DISPLAY BY UNITS OF CELLS OMITTING TRANSFER OF INDIVIDUAL LIGHT-EMITTING ELEMENTS

(71) Applicants: INDUSTRY ACADEMIC COOPERATION FOUNDATION OF YEUNGNAM UNIVERSITY, Gyeongsan-si (KR); ULTECH CO., LTD., Daegu (KR)

(72) Inventors: Si-Hyun PARK, Daegu (KR); Huijin KIM, Daegu (KR); Boseong SON, Daegu (KR)

(73) Assignees: INDUSTRY ACADEMIC COOPERATION FOUNDATION OF YEUNGNAM UNIVERSITY, Gyeongsan-si (KR); ULTECH CO., LTD., Daegu (KR)

(21) Appl. No.: 19/037,005

(22) Filed: Jan. 24, 2025

(30) Foreign Application Priority Data
Mar. 20, 2024 (KR) 10-2024-0038240

(51) Int. Cl. H10H 29/02

(52) U.S. Cl. CPC H10H 29/02

(57) ABSTRACT

Proposed is a method of manufacturing a micro LED display by units of dies omitting transfer of individual light-emitting elements, the method having effects that die-unit display transfer is performed by using a die-unit display, which is composed of light-emitting elements each including a driving element, die-unit display inspection, and a vacuum chuck-based LED pick-and-place transfer method, so that a perpendicular-line gap (ETC, Edge to Chip) between an edge side and an edge chip of each die may be at most half of a chip-to-chip gap (CTC, Chip to Chip), a bonding pad is included within the perpendicular-line gap (ETC) of the edge chip, a bonding gap for each LED die may not exceed half the chip-to-chip (CTC) gap, the driving elements are integrated into the light-emitting elements in a metallization process, and electrical/optical characteristic inspection by units of dies is performed on a wafer.

### CROSS REFERENCE TO RELATED APPLICATION

The present application claims priority to Korean Patent Application No. 10-2024-0038240, filed Mar. 20, 2024, the entire contents of which are incorporated herein for all purposes by this reference.

### BACKGROUND OF THE INVENTION

### Field of the Invention

The present disclosure relates to a technology regarding a method of manufacturing a micro LED display by units of dies omitting transfer of individual light-emitting elements and, more particularly, to a technology regarding a die-unit micro LED display manufacturing method wherein die-unit display transfer is performed by using a die-unit display, which is composed of light-emitting elements each including a driving element, die-unit display inspection, and a vacuum chuck-based LED pick-and-place transfer method, so that a perpendicular-line gap (ETC, Edge to Chip) between an edge side and an edge chip of each die may be at most half of a chip-to-chip gap (CTC, Chip to Chip), a bonding pad is included within the perpendicular-line gap (ETC) of the edge chip, a bonding gap for each LED die may not exceed half the chip-to-chip (CTC) gap, the driving elements are integrated into the light-emitting elements in a metallization process, and electrical/optical characteristic inspection by units of dies is performed on a wafer, so as to enable implementing a display using the simple metallization process as well as transferring only a good quality die.

### Description of the Related Art

A light-emitting diode (LED) is a type of light-emitting elements that emits light when current is applied thereto. The light-emitting diode may emit light at low voltage in a highly efficiency manner, thereby having excellent energy-saving effects.

Recently, the brightness problem of light-emitting diodes has been resolved for great improvement, so light-emitting diodes are being applied to various devices such as backlight units of liquid crystal displays, electronic boards, indicators, and home appliances.

Recently, display devices utilizing light-emitting diodes are being actively developed. Most display device technologies use three light-emitting diode chips (for red, green, and blue) in order to implement one pixel.

However, since driving current is different for each chip, it is difficult to create the same driving circuits. In addition, since the chips are different types of light-emitting diode chips, such chips have a disadvantage of having different lifespans.

A size of a micro light-emitting diode (μ-LED) is at the level of 5 to 100 μm, which is very small, and approximately 25 million pixels or more are required to implement a 4K display device.

Accordingly, there is a temporal problem that it takes at least a month to make one 4K display device by using a simple pick-and-place method.

In addition, an existing micro light-emitting diode (μ-LED) is manufactured on a sapphire substrate and then arranged on a glass substrate or the like by using a physical/chemical transfer method. Here, a transfer process includes a pick-and-place method, a stamp method, and an electrostatic method. The small size and thin thickness of the micro light-emitting diode chip manufactured on the sapphire substrate cause problems such as chip breakage, transfer failure, chip alignment failure, chip tilt occurrence, or the like during the transfer process.

Meanwhile, there is no development yet for a method of manufacturing a micro LED display by units of dies omitting transfer of individual light-emitting elements, that is, a die-unit micro LED display manufacturing method wherein die-unit display transfer is performed by using a die-unit display, which is composed of light-emitting elements each including a driving element, die-unit display inspection, and a vacuum chuck-based LED pick-and-place transfer method, so that a perpendicular-line gap (ETC, Edge to Chip) between an edge side and an edge chip of each die may be at most half of a chip-to-chip gap (CTC, Chip to Chip), the driving elements are integrated into the light-emitting elements in a metallization process, and electrical/optical characteristic inspection by units of dies is performed on a wafer, so as to enable implementing a display using the simple metallization process as well as transferring only a good quality die.

Therefore, there is an urgent need for development of the method of manufacturing the micro LED display by units of dies omitting the transfer of the individual light-emitting elements, that is, the die-unit micro LED display manufacturing method wherein die-unit display transfer is performed by using a die-unit display, which is composed of light-emitting elements each including a driving element, die-unit display inspection, and a vacuum chuck-based LED pick-and-place transfer method, so that a perpendicular-line gap (ETC, Edge to Chip) between an edge side and an edge chip of each die may be at most half of a chip-to-chip gap (CTC, Chip to Chip), a bonding pad is included within the perpendicular-line gap (ETC) of the edge chip, a bonding gap for each LED die may not exceed half the chip-to-chip (CTC) gap, the driving elements are integrated into the light-emitting elements in a metallization process, and electrical/optical characteristic inspection by units of dies is performed on a wafer, so as to enable implementing a display using the simple metallization process as well as transferring only a good quality die.

### Documents of Related Art

(Patent Document 1) KR 10-2054951 (Dec. 12, 2019)

### SUMMARY OF THE INVENTION

Accordingly, the present disclosure is devised to solve the above problems, and an objective of the present disclosure is to provide a method of manufacturing a micro LED display by units of dies omitting transfer of individual light-emitting elements, that is, a die-unit micro LED display manufacturing method wherein die-unit display transfer is performed by using a die-unit display, which is composed of light-emitting elements each including a driving element, die-unit display inspection, and a vacuum chuck-based LED pick-and-place transfer method, so that a perpendicular-line gap (ETC, Edge to Chip) between an edge side and an edge chip of each die may be at most half of a chip-to-chip gap (CTC, Chip to Chip), and a bonding pad is included within the perpendicular-line gap (ETC) of the edge chip.

In addition, another objective of the present disclosure is to provide a method of manufacturing a micro LED display by units of dies omitting transfer of individual light-emitting elements, that is, a die-unit micro LED display manufacturing method wherein a bonding gap for each LED die may not exceed half the chip-to-chip (CTC) gap.

In addition, a yet another objective of the present disclosure is to provide a method of manufacturing a micro LED display by units of dies omitting transfer of individual light-emitting elements, that is, a die-unit micro LED display manufacturing method wherein the driving elements are integrated into the light-emitting elements in a metallization process, and electrical/optical characteristic inspection by units of dies is performed on a wafer, so as to enable implementing a display using the simple metallization process as well as transferring only a good quality die.

According to a preferred exemplary embodiment of the present disclosure to achieve the above objectives, there is provided a method of manufacturing a micro LED display by units of dies omitting transfer of individual light-emitting elements, the method including: step (a) of preparing dies or a wafer on which the light-emitting elements are arranged; step (b) of making a perpendicular-line gap (ETC) between an edge side and an edge chip of each die in the prepared wafer to be at most half of a chip-to-chip gap (CTC) and forming a bonding pad within the gap (ETC); step (c) of implementing the display by a simple metallization process by integrating a driving element into each light-emitting element; and step (d) of performing electrical/optical characteristic inspection by units of dies on the wafer and transferring only a good quality die.

In the present disclosure, step (b) may include ensuring a bonding gap for each LED die not to exceed half of the chip-to-chip (CTC) gap.

In the present disclosure, step (c) may include allowing monolithic integrated devices to be arranged in a case of the wafer on which the metallization process has been completed by units of dies.

In the present disclosure, step (d) may include allowing a die of 360 PPI to be transferable when a LED chip size is 50×50 μm² and a pitch is 100 μm in a case of transferring the good quality die.

In the present disclosure, step (d) may include performing die-unit display transfer by using a vacuum chuck-based LED pick-and-place transfer method.

In the present disclosure, the method may further include reducing a transfer count by 1/PPI² when the die-unit transfer is performed.

The method for manufacturing the micro LED display by units of dies omitting the transfer of the individual light-emitting elements according to the present disclosure exhibits the following effects.

First, in the present disclosure, die-unit display transfer is performed by using a die-unit display, which is composed of light-emitting elements each including a driving element, die-unit display inspection, and a vacuum chuck-based LED pick-and-place transfer method, so that a perpendicular-line gap (ETC: Edge to Chip) between an edge side and an edge chip of each die may be at most half of a chip-to-chip gap (CTC: Chip to Chip), and a bonding pad is included within the perpendicular-line gap (ETC) of the edge chip.

Second, in the present disclosure, a bonding gap for each LED die may not exceed half the chip-to-chip (CTC) gap.

Third, in the present disclosure, the driving elements are integrated into the light-emitting elements in a metallization process, and electrical/optical characteristic inspection by units of dies is performed on a wafer, so as to enable implementing a display using the simple metallization process as well as transferring only a good quality die.

### BRIEF DESCRIPTION OF THE DRAWINGS

FIG. 1 is a view illustrating a shape of a light-emitting element including a transistor function in a die-unit display according to an exemplary embodiment of the present disclosure.

FIG. 2 is a view illustrating processes starting from a preparation process for dies or a wafer on which elements are arranged ending to a metallization process in the die-unit display according to the exemplary embodiment of the present disclosure.

FIG. 3 is a view illustrating a die-unit transfer process according to the exemplary embodiment of the present disclosure.

FIG. 4 is a view illustrating a bonding gap for each LED die in the die-unit transfer process according to the exemplary embodiment of the present disclosure.

FIG. 5 is a flowchart of manufacturing a micro LED display by units of dies omitting transfer of individual light-emitting elements according to the exemplary embodiment of the present disclosure.

### DETAILED DESCRIPTION OF THE INVENTION

Hereinafter, a preferred exemplary embodiment of the present disclosure will be described as follows with reference to the attached drawings. In describing the present disclosure, in a case where it is determined that a detailed description of a related known technology or configuration may unnecessarily obscure the gist of the present disclosure, the detailed description will be omitted. The terms described below are terms defined in consideration of their functions in the present disclosure, and may vary depending on the intention of a user or operator, custom, or the like, so the definitions should be based on the content throughout the present specification describing a method of manufacturing a micro LED display by units of dies omitting transfer of individual light-emitting elements of the present disclosure.

Hereinafter, the method of manufacturing the micro LED display by units of dies omitting the transfer of the individual light-emitting elements according to the exemplary embodiment of the present disclosure is described in detail.

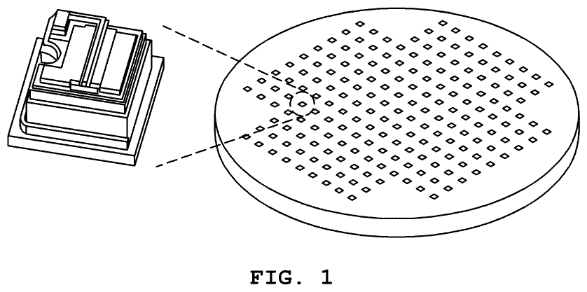

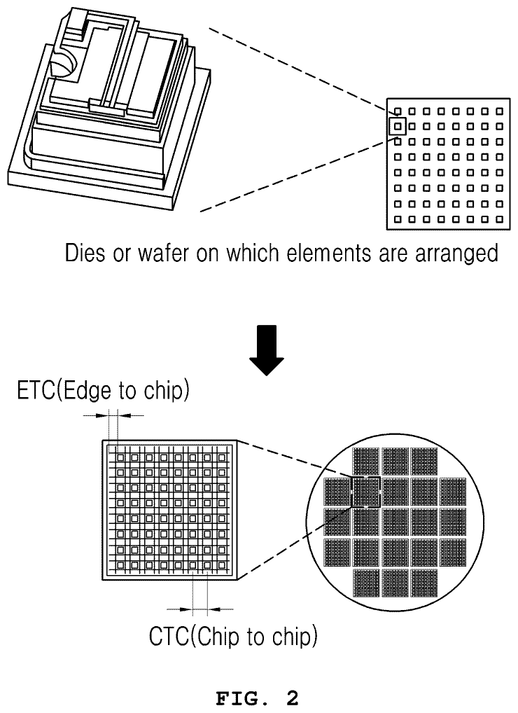

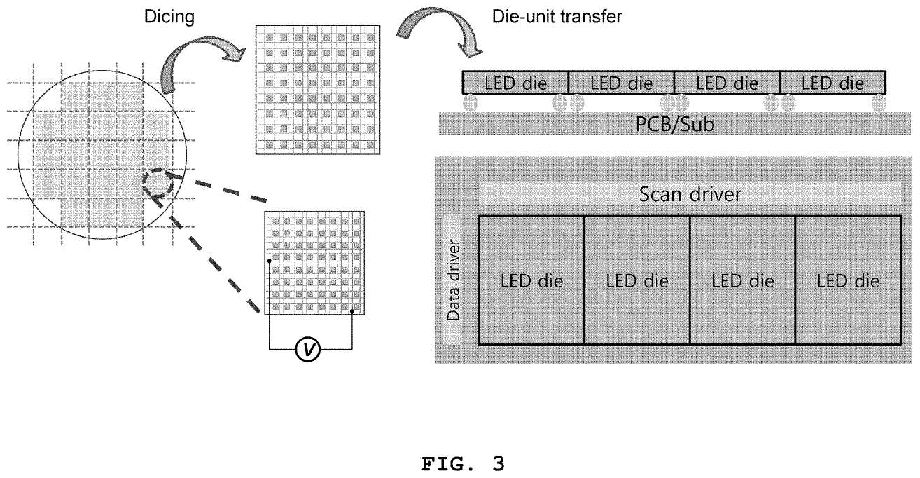

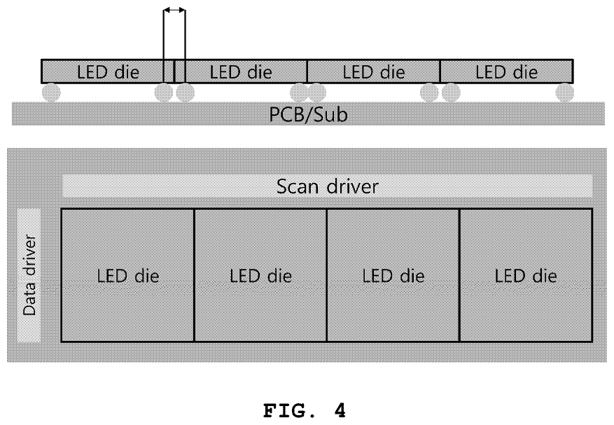

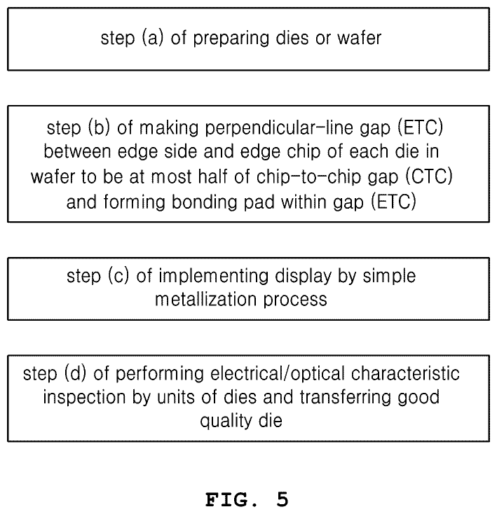

FIG. 1 is a view illustrating a shape of a light-emitting element including a transistor function in a die-unit display according to an exemplary embodiment of the present disclosure. FIG. 2 is a view illustrating processes starting from a preparation process for dies or a wafer on which elements are arranged ending to a metallization process in the die-unit display according to the exemplary embodiment of the present disclosure. FIG. 3 is a view illustrating a die-unit transfer process according to the exemplary embodiment of the present disclosure. FIG. 4 is a view illustrating a bonding gap for each LED die in the die-unit transfer process according to the exemplary embodiment of the present disclosure. FIG. 5 is a flowchart of manufacturing a micro LED display by units of dies omitting transfer of individual light-emitting elements according to the exemplary embodiment of the present disclosure.

As illustrated in FIGS. 1 to 5, the method of manufacturing the micro LED display by units of dies omitting the transfer of the individual light-emitting elements includes: step (a) of preparing dies or a wafer on which the light-emitting elements are arranged; step (b) of making a perpendicular line gap (ETC) between an edge side and an edge chip of each die in the prepared wafer to be at most half of a chip-to-chip gap (CTC) and forming a bonding pad within the gap (ETC); step (c) of implementing the display by a simple metallization process by integrating a driving element into each light-emitting element; and step (d) of performing electrical/optical characteristic inspection by units of dies on the wafer and transferring only a good quality die.

The functions of technical steps constituting a method of manufacturing a micro LED display by units of dies omitting transfer of individual light-emitting elements are as follows:

First, in step (a) of preparing dies or a wafer, the dies or wafer on which an light-emitting elements are arranged.

Second, in step (b) of making a perpendicular line gap (ETC) between an edge side and an edge chip of each die in a wafer to be at most half of a chip-to-chip gap (CTC) and forming a bonding pad within the gap (ETC), the perpendicular-line gap (ETC) between the edge side and the edge chip of each die is made to be at most half of the chip-to-chip gap (CTC) in the prepared wafer, and the bonding pad is formed within the gap (ETC).

Here, the bonding gap for each LED die should not to exceed half of the chip-to-chip (CTC) gap.

In addition, for example, in a case where a chip-to-chip gap (CTC: chip to chip) is 500 μm, a bonding gap for each LED die should be defined to be 250 μm or less.

Third, in step (c) of implementing a display by a simple metallization process, driving elements are integrated into the light-emitting elements, so that the display may be implemented through the simple metallization process.

Here, in a case of the wafer on which the metallization process has been completed by units of dies, monolithic integrated devices may be arranged thereon.

Fourth, in step (d) of performing electrical/optical characteristic inspection by units of dies on the wafer and transferring only a good quality die, the electrical/optical characteristic inspection by units of dies is performed on the wafer and only the good quality die is transferred.

Here, in the case of transferring only the good quality die, each die of 360 PPI is transferable when an LED chip size is 50×50 μm² and a pitch is 100 μm.

In addition, the die-unit display transfer is performed by using a vacuum chuck-based LED pick-and-place transfer method.

TABLE 1

| | Samsung The Wall |
|---|---|
| Resolution | 4K (3840 × 2160) |
| Pixel count | approximately 24,000,000 |
| PPI | 30 |
| Transfer count for individual | approximately 24,000,000 |
| light-emitting elements | |
| Transfer count by units of dies | approximately 27,000 |

Calculated figures based on die area (1×1 inch²), PPI 30

In the characteristics of die-unit micro LED display in the [Table 1], the transfer count may be reduced by 1/PPI² when die-unit transfer is performed through the method of manufacturing the micro LED display by units of dies omitting the transfer of the individual light-emitting elements.

As described above, the method for manufacturing the micro LED display by units of dies omitting the transfer of the individual light-emitting elements is applicable to the field of micro LED displays, so its application scope is wide.

The best exemplary embodiment is disclosed in the drawings and specification, and the terms used herein are used only for the purpose of describing the present disclosure, and are not used to limit the meaning or the scope of the present disclosure described in the claims. Therefore, those skilled in the art will be able to make various modifications and equivalent other exemplary embodiments from this, and accordingly, the true technical protection scope of the present disclosure should be determined by the technical idea of the appended patent claims.

This invention was supported by the Regional Innovation Strategy (RIS) of the National Research Foundation of Korea (NRF), funded by the Ministry of Education (MOE) (Grant No. 2022RIS-006).

What is claimed is:

1. A method of manufacturing a micro LED display by units of dies omitting transfer of individual light-emitting elements, the method comprising:
step (a) of preparing dies or a wafer on which the light-emitting elements are arranged;
step (b) of making a perpendicular-line gap (ETC) between an edge side and an edge chip of each die in the prepared wafer to be at most half of a chip-to-chip gap (CTC) and forming a bonding pad within the gap (ETC);
step (c) of implementing the display by a simple metallization process by integrating a driving element into each light-emitting element; and
step (d) of performing electrical/optical characteristic inspection by units of dies on the wafer and transferring only a good quality die.

2. The method of claim 1, wherein step (b) comprises ensuring a bonding gap for each LED die not to exceed half of the chip-to-chip (CTC) gap.

3. The method of claim 1, wherein step (c) comprises allowing monolithic integrated devices to be arranged in a case of the wafer on which the metallization process has been completed by units of dies.

4. The method of claim 1, wherein step (d) comprises allowing a die of 360 PPI to be transferable when a LED chip size is 50×50 μm² and a pitch is 100 μm in a case of transferring the good quality die.

5. The method of claim 1, wherein step (d) comprises performing die-unit display transfer by using a vacuum chuck-based LED pick-and-place transfer method.

6. The method of claim 1, further comprising:
reducing a transfer count by 1/PPI² when the die-unit transfer is performed.
